(19) United States
(12) Patent Application Publication
(10) Pub. No.: US 2015/0036969 A1
(43) Pub. Date: Feb. 5, 2015

(54) DISPERSION PLATE FOR CHEMICAL VAPOR DEPOSITION PROCESSES TO FORM DOPED FILMS

(71) Applicant: LGS Innovations LLC, Herndon, VA (US)

(72) Inventors: Hugo Safar, Herndon, VA (US); Mike Santo, Herndon, VA (US); Brijesh Vyas, Herndon, VA (US)

(73) Assignee: LGS Innovations LLC, Herndon, VA (US)

(21) Appl. No.: 13/956,166

(22) Filed: Jul. 31, 2013

(51) Int. Cl. C23C 16/455; G02B 6/12

(52) U.S. Cl. CPC C23C 16/45565; G02B 6/12; G02B 2006/12166
USPC 385/14; 118/715; 427/255.28; 427/96.8; 264/628

(57) ABSTRACT

An apparatus comprising a dispersion plate, a dispersion plate, the dispersion plate including input side openings connected to holes therein, the holes following a torturous path through the dispersion plate and configured to deliver dopants through output side openings of the dispersion plate.

### TECHNICAL FIELD

The invention relates to in general, to a chemical vapor deposition (CVD) apparatus, methods for manufacturing the same, and CVD processes using such an apparatus.

### BACKGROUND

This section introduces aspects that may help facilitate a better understanding of the inventions. Accordingly, the statements of this section are to be read in this light and are not to be understood as admissions about what is prior art or what is not prior art.

Electronic devices, such as integrated circuits, often include component parts which include films formed by CVD processes. Often, as part of forming such films, gases are passed through a dispersion plate (also known in the industry as a showerhead) of a CVD apparatus.

### SUMMARY

One embodiment is a chemical vapor deposition apparatus comprising a dispersion plate, the dispersion plate including input side openings connected to holes therein, the holes following a torturous path through the dispersion plate and configured to deliver dopants through output side openings of the dispersion plate.

In any embodiments of the apparatus, one or more major axes of the holes can be substantially non-perpendicular to an output surface of the dispersion plate. In any embodiments of the apparatus, an average diameter of the output side openings can be less than an average diameter of the input side openings. In any embodiments of the apparatus, end openings of the holes can have an average diameter of 400 microns or less and the average diameter of the holes can be greater than an average diameter of molecules of the dopants. In any embodiments of the apparatus, the output side openings of the holes can have a smaller average diameter on than the average diameter of the input side openings. In any embodiments of the apparatus, an average area of the output side of the holes can have a standard deviation of about ±20 percent. In any embodiments of the apparatus, an average separation distance between adjacent ones of the output side openings can be substantially equal to the average diameter of the output side openings. In any embodiments of the apparatus, the torturous path of the holes can include at least one internal bend region which forms a bend angle of at least about 30 degrees between two different major axes of different portions of the same hole. In any embodiments of the apparatus, the holes can form an interconnected porous network. In any embodiments of the apparatus, the plate can be composed of an electrically conductive material. Any embodiments of the apparatus can further include a reactor assembly configured to hold the dispersion plate inside of a deposition chamber, the reactor assembly configured to be coupled to a gas delivery system. In any embodiments of the apparatus, the dispersion plate can be configured to regulate exposure of an adjacent surface of a deposition substrate to gases delivered to the reactor assembly, the gases including the dopants having elements of atomic number 21 or higher.

Another embodiment is a method that comprises forming a dispersion plate of a chemical vapor deposition apparatus, the dispersion plate including input side openings connected to holes therein, the holes following a torturous path through the dispersion plate and configured to deliver dopants through output side openings of the dispersion plate.

In some embodiments of the method, forming the dispersion plate can include placing metallic or inorganic non-metallic material particles into a mold of the dispersion plate. Forming the dispersion plate can also include sintering adjacent ones of the particles to together to form the dispersion plate wherein open spaces between the sintered together particles correspond to the holes of the dispersion plate.

Another embodiment is a circuit comprising a doped film on a substrate, the doped film including one or more dopants elements having an atomic number 21 or higher, wherein the film has a light loss of about 2 dB/m or less.

In any embodiments of the circuit, the light losses can be at wavelengths in the S band, C band or L band range. In any embodiments of the circuit, the doped film can be substantially free of defects each having diameter of greater than about 500 microns. In any embodiments of the circuit, the doped film is substantially free of individual defect clusters each having diameter of greater than about 500 microns.

Another embodiment is a method comprising forming a doped film on a substrate. Forming the doped film includes passing vapors of one or more types of dopant elements having an atomic number 21 or higher through a dispersion plate, the dispersion plate including holes therein, the dispersion plate including input side openings connected to holes therein, the holes following a torturous path through the dispersion plate and configured to deliver dopants through output side openings of the dispersion plate.

In some embodiments of the method, the dispersion plate can be maintained at a temperature of about 700° C. or less while passing the vapors through the dispersion plate. In some embodiments of the method can further include patterning the doped film to form one or more waveguides of a component of a planar lightwave circuit.

### BRIEF DESCRIPTION OF THE DRAWINGS

The embodiments of the disclosure are best understood from the following detailed description, when read with the accompanying figures. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a block diagram of an apparatus;

FIG. 2A presents a plan view of dispersion plate of an apparatus such as any plate and apparatus discussed in the context of FIG. 1;

FIG. 2B presents a detailed plan view of a portion of the dispersion plate such as the plate shown in FIG. 2A;

FIG. 2C presents a detailed plan view of a portion of the dispersion plate such as the plate shown in FIG. 2A;

FIG. 3 presents a detailed cross-sectional view of a portion of the dispersion plate such as the dispersion plate shown in FIG. 1;

FIG. 4 presents a flow diagram of an example method of manufacturing an apparatus, such as any of the apparatuses described in the context of FIGS. 1-4;

FIG. 5 presents a detailed cross-sectional view of a circuit, such as a circuit having at least one component that is at least partially fabricated by any of the apparatus embodiments discussed in the context of FIGS. 1-4; and

FIG. 6 presents a flow diagram of an example method, such as a method to fabricating any circuit described in the context of FIG. 5.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION OF ILLUSTRATIVE EMBODIMENTS

The description and drawings merely illustrate the principles of the inventions. It will thus be appreciated that a person of ordinary skill in the relevant arts will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

There is growing interest in using CVD processes to form component parts of planar lightwave circuits (PLCs). In particular, there is an interest in forming doped films, such as rare earth element doped films, which are subsequently patterned to form light generating or amplifying components (e.g., diodes, lasers or light amplifiers) of PLCs. It is believed, however, that conventional CVD apparatuses, intended to be used in the fabrication of electronic device components, were ineffective for forming such doped films.

For instance, when films are doped with elements of high atomic number, such as rare earth elements, are patterned to form waveguides (e.g., the waveguides of lasers or light amplifiers) the waveguides can have unacceptably high light losses (e.g., about 10 dB per meter (dB/m), or about 20 dB/m, or higher losses in some cases). It was discovered that such doped films contain visibly opaque defect regions. Such defect regions can cause light scattering losses in PLC components formed from or including such films. It is the inventor's belief that the defect regions may correspond to clusters of rare elements and ligand precursor complexes that formed small bubbles or precipitates within the doped films. Often such defect clusters are visible across the surface of, and/or within, the deposited doped film.

It was further discovered that there was a pattern of such defect regions in the doped film which inventors believe correlate with the pattern of openings present in the dispersion plate of the CVD apparatus used to deposit the doped film and such defect regions seem to be less present in similar undoped films. The inventors believe that vapors of ligand precursor complexes containing dopant elements having a high atomic number, have limited diffusion through the space between the output side of the dispersion plate and the substrate surface upon which the doped film is formed. Thus, it is believed that such dopant elements containing-ligand precursor complexes tend to cluster in the portions of the film that lay immediately below the locations of the openings in the dispersion plate, and, that the growth of the clusters lead to the formation of the defect regions in the film.

The inventors believe that one or more physical characteristics of the dispersion plate can be modified to reduce the size and number of opaque defect regions. Such physical characteristics can include the size, orientation, density and distribution of holes in the plate, and/or the thickness of the plate. That is, one or more of the ranges of opening size, density or distribution, orientation of holes or the porosity and thickness of the plate, are believed by the inventors to be newly discovered result-effective variables that influence the uniformity of the distribution of dopant elements having a high atomic number in CVD films, as further discussed below.

One embodiment is an apparatus. In some embodiments, the apparatus can be or include a plasma enhanced chemical vapor deposition (PECVD) apparatus or a metal organic chemical vapor deposition (MOCVD) apparatus. Based on this disclosure, one of ordinary skill in the pertinent arts would readily be able to make and use other embodiments of the apparatus configured as a CVD apparatus.

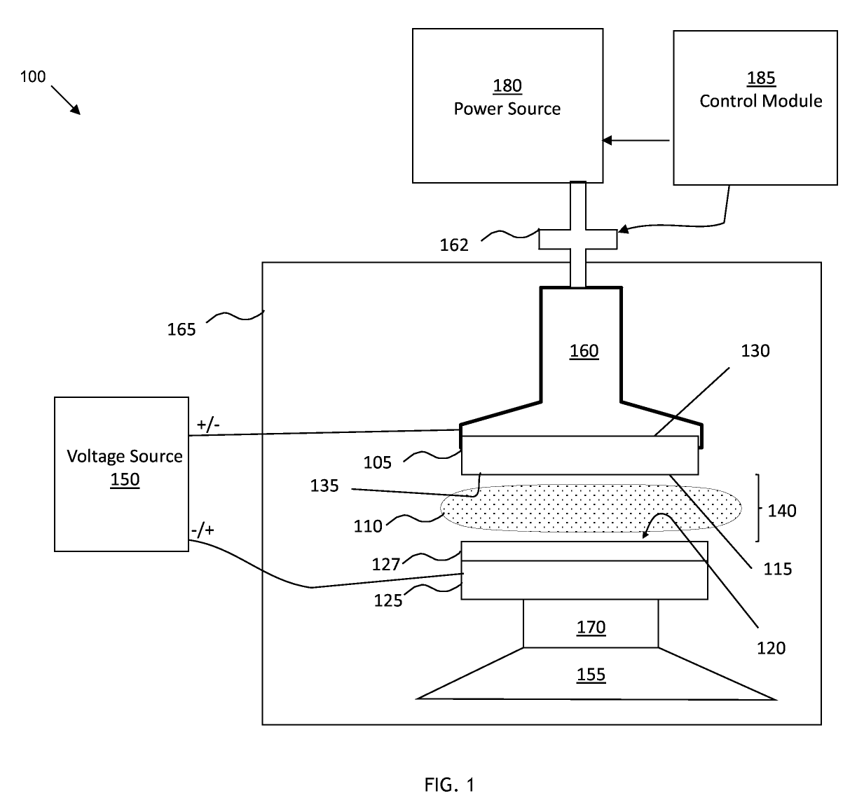

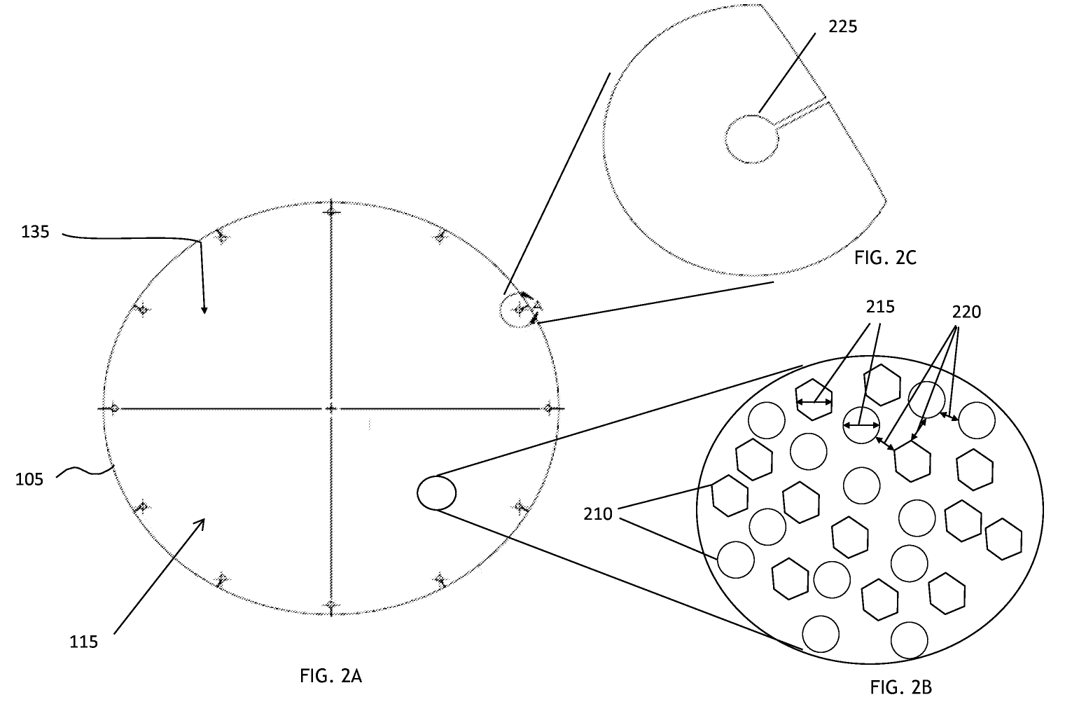

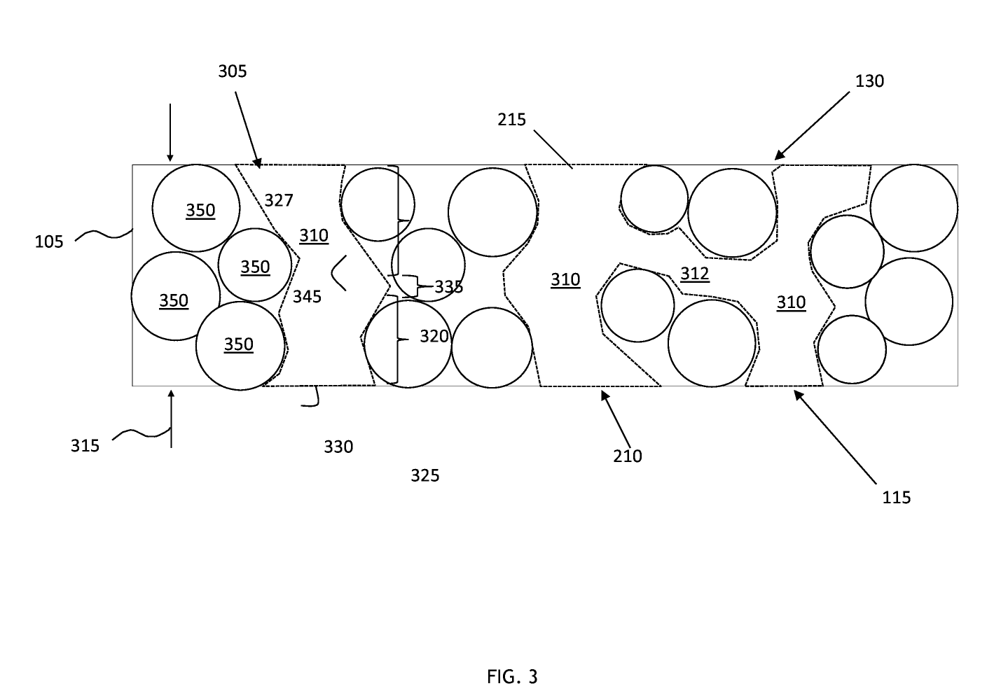

FIG. 1 presents a block diagram of an embodiment of the apparatus 100. FIG. 2A presents a plan view of dispersion plate 105 of the apparatus 100. FIG. 2B presents a detailed plan view of a portion of the dispersion plate 105 presented in FIG. 2A, showing output side openings 210. FIG. 2C presents a detailed plan view of another portion of the dispersion plate 105 shown in FIG. 2A. FIG. 3 presents a detailed cross-sectional view of a portion of the dispersion plate 105 shown in FIG. 1.

With continuing reference to FIGS. 1-3, the apparatus 100 comprises the dispersion plate 105, or in some embodiments, a plurality of dispersion plates 105, e.g., for a multi-substrate station CVD apparatus.

The dispersion plate 105 includes input side openings 305 connected to holes 310 therein. The holes 310 following a torturous path through the dispersion plate 105 and configured to deliver dopants 110 through output side openings 210 of the dispersion plate 105

As illustrated, the input openings 305 are in a major surface of the plate 105 that corresponds to the dopant input side 130 of the plate 105, and, the output openings 210 are in an opposing major surface that corresponds to the dopant output side of the plate 105.

The term torturous path, as used herein, means that there are no straight paths through the plate 105. The non-straight twisting and winding torturous pathways through the plate 105 promotes the mixing of dopant molecules 110 within the plate 105.

Such mixing helps deliver a substantially uniform distribution of dopants 110 through an output side 115 of the plate 105. For instance, in some cases, during operation of the apparatus 100, the concentration of dopants in the space adjacent to different areas of the output side 115 of the plate 105 are substantially the same (e.g., within about 20 percent, and in some cases within about 10 percent). The distribution of dopants 110 through the output side 115 of the plate 105 facilitates the uniform distribution of dopants 110 to the surface 120 of a substrate 125 facing the dispersion plate 105, to form a doped film 127. The doped film 127, in turn, can have a uniform distribution of dopants therein, e.g., as indicated by the absence of defects and low light losses as further discussed below.

For the reasons discussed above, the inventors believe that the apparatus 100 facilitates the formation of substantially defect-free doped films, where the dopant has a high atomic number. The term high atomic number, as used herein, refers to dopants having one or more elements with an atomic number of 21 or higher. In some embodiments, the dopant elements include one or more rare earth element, which is defined as the fifteen lanthanides (atomic numbers 57 through 71) elements, plus scandium (atomic number 21) and yttrium (atomic number 39). It is thought that the dispersion plate 105 is particularly useful for the formation of rare earth element doped films forming certain components parts of PLCs. In other embodiments, however, the dopant elements can include non-rare earth elements having a high atomic number. Non-limiting examples include transition metal elements having an atomic number of 22 or higher, or in some embodiments an atomic number or 40 or higher.

One skilled in the pertinent arts would understand how vapors of the dopants 110 could be carried through the dispersion plate 105 along with other deposition gas components that are used to form the doped film 127, such as further discussed below.

One or more of the size, distribution and density of output side openings 210 (FIG. 2B) of the holes 310 (FIG. 3), and/or the orientation of the holes 310 in the plate 105, can be adjusted as parameters to facilitate mixing (e.g., turbulent mixing) of the dopants 110 exiting from the holes 310 of the plate 105. Promoting mixing of the dopants, in turn, facilitates the delivery of a uniform distribution of the dopant 110 to the substrate 125 surface 120 upon which a doped film 127 is formed, e.g., by a CVD process. The value of the parameters may selected in a way the balances the desire for uniformity of dopants in doped film 127, with the desire for a high flow rate.

Having near-microscopic or microscopic-sized openings 210 on at least an output side 115 (e.g., deposition gas and vapor output) of the dispersion plate 105. In some embodiments, the size of the openings 210, 305 of one or both the output side 115 and the input side 130, can be selected to facilitate the formation of a high density of openings 210 in the plate 105. Having a high density of microscopic openings 210, in turn, can also facilitate forming a uniform concentration of the dopants 110 at the output side 115 and reaching the substrate surface 120.

For instance, in some embodiments of the plate 105, the openings 210 of the holes 310 on an output side 115 (e.g., a planar side in some embodiments) of the dispersion plate 105 have an average diameter 215 of about 400 microns or less and in some embodiments, 100 microns or less. In some embodiments, the average diameter 215 equals about 200 microns, and in some embodiments, about 100 microns, and, in some embodiments, about 50 microns. In some embodiments, the average diameter 215 of the through-holes is preferably greater than an average diameter of the individual dopant molecules, and in some cases, at least 10 times, and in some cases 100 times, greater than the average diameter of the individual dopant molecules. In some embodiments, the average diameter 215 is in a range of about 50 to 150 microns. This can be in contrast to certain conventional dispersion plates, with openings that may have a diameter of at least five to ten times larger than the average diameter 215 of the openings 210 in the dispersion plate 105.

In some embodiments of the plate 105, the output side openings 210 and cross-sections through the holes 310 (e.g., cross-sections parallel to the output side 115) can be substantially circular. In other embodiments, the openings 210 and cross-sections through the holes 310 can be non-circular, and in some embodiments, irregularly shaped. In such instances, the average area of individual openings can be equivalent to the areas of substantially circular openings with the above-disclosed average diameters.

For instance, in some embodiments, the average area of the openings 210 equals about 0.125 mm² or less, equivalent to the average areas of circular openings 210 having an average diameter 215 of about 400 microns or less. For instance, in some embodiments, the average area of the openings 210 equals about 0.0078 mm² or less, equivalent to the average areas of circular openings having an average diameter 215 of about 100 microns or less.

In some embodiments, to provide tight control over the velocity and diffusion rates of the dopants 110 exiting the plate 105, the 215 diameters (or equivalent areas) of the openings 210 can be distributed over a narrow range. For instance, in some embodiments, the standard deviation of the average diameters of the openings 210 can equal about ±20 percent, and in some embodiments, about ±10 percent, and in some embodiments, about ±5 percent. For example, in some embodiments, an average diameter 210 of the openings 210 can equal 100±20 microns. For example, in some embodiments, an average area of the openings 210 of the holes has a standard deviation of about ±20 percent.

In other embodiments, the sizes of the openings 210, 305 on the output and input sides 115, 130 of the plate 105 can vary over a broad range. While not being limited by theory, it is thought that appropriately selecting the size of openings 210 can cause the dopant 110 to exit the openings 210 at selected velocities which, in turn, can facilitate mixing between dopant 110 exiting different openings 210. In some embodiments, the plate 105 may be configured to have holes 310 whose output side openings 210 have a wide range of average diameters, e.g., an approximately random distribution of average diameters. For such embodiments, the velocities of the dopants 110 exiting the plate 105 may have a wide distribution.

For instance, in some embodiment, the openings 210 may have average diameters 215 that are roughly equally distributed in the range of about 50 microns to about 400 microns, or some sub-range thereof, e.g., 50 micron to 200 microns. For example, in some embodiments, there can be five different groupings of opening 210 sizes corresponding to openings 210 with average group diameters 215 of 50, 75, 100, 125 and 150 microns, respectively, in about equal portions (e.g., each opening size is about 20 percent total number of openings). For example, in some cases, the size distribution of openings 210 provides the same proportions of the total open area of one or both the output and input sides 115, 130 of the plate 105. For instance, continuing with the same example, in some embodiments, the five different groups of openings 210 can each correspond to about 20 percent of the total open area of one or both the output and input sides 115, 130 of the plate 105.

In some embodiments, the openings 210, 305 on the output and input sides 115, 130 of the plate 105 can be substantially the same size. For instance, in some embodiments, the average diameters 215 or areas of the openings 210, 305 on the input and output sides 115, 130 of the plate 105 are the same within about 10 percent, and in some embodiments, within about 5 percent, and in some embodiments, within about 1 percent.

In some embodiments, the distribution of the size, e.g., average diameters 215, of the cross-sections of the holes 310 is constant through the thickness 315 of the plate 105 (e.g., average diameter or equivalent area of cross-sections parallel to the output side 115). In other embodiments, the size can vary across the thickness 315. In some embodiments, the output side openings 210 of the holes 310 have an average diameter 215 (e.g., at least about 10 percent less) than the average diameter of the input side openings 305. In some embodiments, the average diameters 215 of the holes 310 can be progressively or step-wise decrease, or alternatively increase, from the input side 130 to the output side 115 of the plate 105. In some embodiments, decreasing the average diameters 215 of the holes 310 from the input side 130 to the output side 115 can accelerate the velocity of the dopant 110 exiting plate 105 and thereby advantageously promote mixing between dopants exiting different openings 210.

In some embodiments, to increase the density of the openings 210, 305 e.g., on the output side 115, or both the input and output sides 115, 130, the average separation distance 220 between adjacent openings 210 (e.g., nearest edge of the opening to the nearest edge of the adjacent opening) can equal about 400 microns or less, or in some embodiments about 100 microns or less, or in some embodiments, about 50 microns or less. In some embodiments, an average separation distance 220 between adjacent ones of the output side openings 210 are substantially equal (e.g., with 10 percent) to the average diameter 215 of the output side openings 210. For instance, if the average output side openings 210 diameter 215 is 100 microns then the perimeters of adjacent openings 210 have an average separation distance 220 of 100 microns±20 microns. A similar relationship can exist for the input side openings 305 or the holes 310 within the plate 105.

In some embodiments, the density of the openings 210 can be randomly distributed over the output side 115 (and in some embodiments the input side 130) of the plate 105. However, a pseudo-random pattern of openings 115 is not excluded. In some embodiments, for any contiguous and convex 10 percent, and in some embodiments, any 1 percent area, of the total area of the output side 130, the number of openings 210 is within 20 percent and in some embodiments 10 percent, of the number of openings in any different same-sized area of the side 130.

In some embodiments, for the majority of holes 310 in the plate 105, the orientation of at least a portion 320 the holes 310, are non-perpendicular relative to plane of an outer surface 135 of the output side 115 of the plate. In some embodiments, one or more major axes 325 of the holes 310 are substantially non-perpendicular to the plane of the output surface 135. For instance, the major axes 325 can form an angle 330 with respect to the plane of the output surface of at least degrees, and in some embodiments in a range of 25 to 75 degrees, and in some embodiments in a range of 35 to 60 degrees. In some embodiments, the portion 320 of the holes 310 with the non-perpendicular major axes 325 corresponds, on average to at least about 10 percent, and in some embodiments, at least about 50 percent, of a total path length of the hole 310.

While not being limited by theory, having at least a portion 320 with a non-perpendicular orientation is believed by the inventors to promote turbulent mixing of the dopants 110 exiting from adjacent holes 310 to thereby facilitate homogenizing and uniformly distributing the concentration of the dopants 110 in the space 140 between the dispersion plate 105 and the substrate 115. This is in contrast to certain conventional dispersion plates, with large diameter (e.g., about 1000 micron or larger) holes that are substantially straight and perpendicularly oriented with respect to an output side.

In some embodiments, the majority (e.g., over about 50 percent), and in some embodiments substantially all (e.g., over about 90 percent) of the holes 305 in the plate 105 have a tortuous pathway through the plate 105. In some embodiments, as part of the tortuous pathway, each of the holes 305 have a least one internal bend region 335 therein, the bend region defined by a bend angle 345 of at least about 30 degrees between two different major axes 325, 327 of different portions of the same hole 310 (e.g., portion 320 and second portion 340) on either side of the bend region 335. In some embodiments, the tortuous pathway of the individual holes 305 can have multiple such bend regions 335 along the length of each of the holes 310 in the interior of the plate 105.

Additionally, the porosity and/or the thickness 315 of the plate 105 can be selected and adjusted as parameters to further facilitate mixing of the dopants leaving the holes 310 and to provide a flow rate adequate to ensure the rapid formation of the dopant layer 127.

In some embodiments, the holes 310 form an interconnected porous network. In some embodiments, for the majority of the holes 310 (e.g., at least about 50 percent) the pathway of one hole 310 intersects, e.g., in an interior intersection region 312, with the pathway of at least another hole 310. In some embodiments, forming a porous network of holes 310 promotes the mixing of dopants and a uniform distribution of dopants 110 leaving the output side 115 and being adjacent to and outside of the output side 115 and also facilitate a high flow rate of dopants 110 and other deposition gases through the plate 105.

In some embodiments, to facilitate a uniform distribution of dopants 110 reaching an adjacent surface of the substrate 125, to facilitate a high flow rate of dopants 110 and other deposition gas through the plate 105, and, to facilitate the plate 105 having sufficient mechanical strength to tolerate repeated heating cycles, the plate 105 has a thickness 315 in a range about 2 to 10 mm and in some embodiments about 2 to 4 mm and in some embodiments, about 3 mm±10 percent.

In some embodiments, the plate 105 is composed of an electrically conductive material (e.g., steel, aluminum, titanium). In some such cases, the plate 105 can be electrically connected to a voltage source 150 of the apparatus 100 and serve as a cathode (+) or an anode (−) plate of the apparatus 100, e.g., configured as a PECVD apparatus. In such embodiments, the substrate 125 may rest on an electrically conductive support pedestal or platform 155 that is also connected to the voltage source 150 and serves as the other of the anode or cathode for the apparatus 100.

In other embodiments, the plate 105 can be formed and composed of a non-electrically conducting material. Non-limiting examples include ceramic materials such as silicon carbide and similar materials. Non-electrically conducting plates can be used for metal-organic chemical vapor deposition (MOCVD), or other CVD processes familiar to one skilled in the pertinent arts.

As further illustrated in FIG. 1, in some embodiments, the apparatus 100 can include a reactor assembly 160, and, the reactor assembly 160 is configured to hold the plate 105 and is also configured to be coupled to a gas delivery system 162. The gas delivery system 162 is configured to deliver deposition materials, via the reactor assembly 160, to the input side 130 of the plate 105. The dispersion plate 105 is configured to regulate exposure of an adjacent surface of a deposition substrate 125 to gases delivered to the reactor assembly 160 by the delivery system 162, the gases including the dopants having elements of atomic number 21 or higher. As illustrated in FIG. 2C, some embodiments of the plate 105 include mounting holes 225, e.g. located around a perimeter of the plate 105, to secure the plate 105 to the reactor assembly 160. In some embodiments, the plate 105 can have a shape, dimensions and mounting holes 225 locations to substantially match the mounting location for a gas dispersion plate, e.g., a shower head, of a conventional reactor assembly 160.

As further illustrated in FIG. 1, in some embodiments, the apparatus 100 further includes other components, e.g., of a CVD apparatus. Such other components can include a deposition chamber 165, heating module 170, gas delivery system 175 to control the inlet and outlet of deposition materials into and out of the chamber 165. Some embodiments of the apparatus 100 can include a radio-frequency power source 180 used to generate a plasma inside the deposition chamber 165 and control module 185 (e.g., a computer) configured to control the flow of deposition material, and/or, the chamber's pressure and temperature and/or the deposition substrate's temperature.

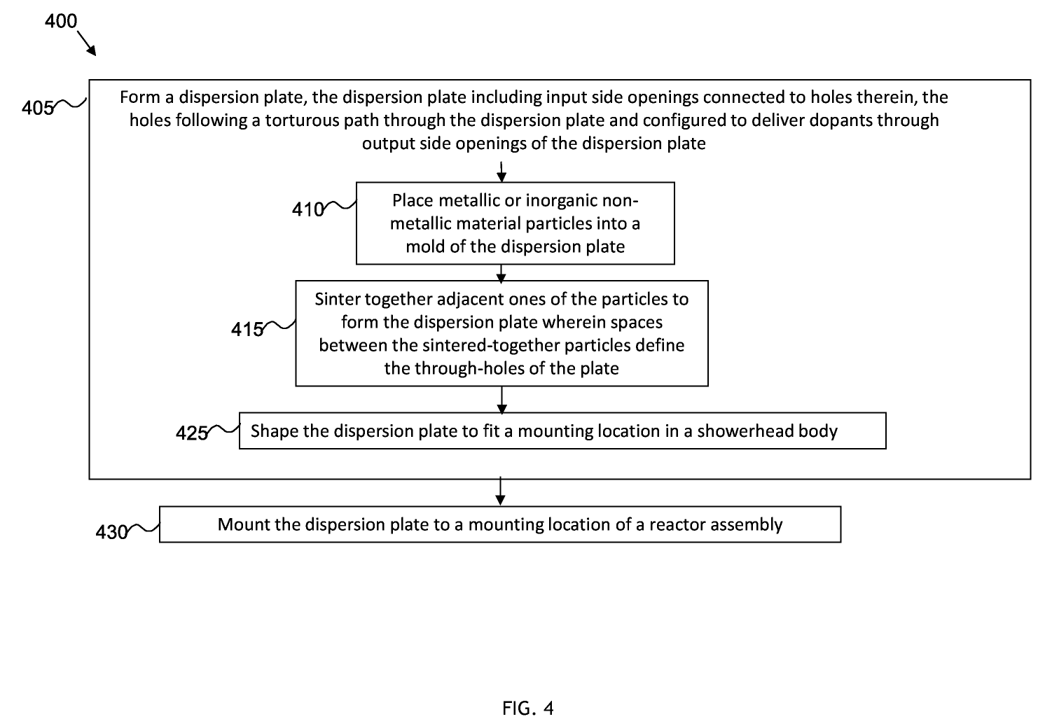

Another embodiment is a method, e.g., a method of manufacturing a CVD apparatus. FIG. 4 presents a flow diagram of an example method 400 of manufacturing an apparatus, such as any of the apparatuses 100 described in the context of FIGS. 1-3. With continuing reference to FIGS. 1-4, the method comprises a step 405 of forming a dispersion plate 105. The dispersion plate 105 includes input side openings 305 connected to holes 310 therein, the holes 310 following a torturous path through the dispersion plate 105 and configured to deliver dopants 110 through output side openings 210 of the dispersion plate 105.

As discussed above in the context of FIGS. 1-3, the holes 310 can be configured to deliver a substantially uniform distribution of dopants 110 through an output side 115 of the dispersion plate 105.

In some embodiments, forming the plate (step 405) includes a step 410 of placing metallic or inorganic non-metallic material particles into a mold of the dispersion plate. Forming the plate (step 405) can also include a step 415 of sintering adjacent ones of the particles 350 together to form the dispersion plate 105 wherein spaces between the sintered-together particles 350 define the holes 310 of the plate 105.

The term sintering, as used herein, refers to a combination of elevated temperature and pressure to cause the particles 350 to fuse together without substantially degrading the intrinsic shape and size of the individual particles 350. Sintering results in the formation of a unitary, single connected material piece that can corresponding to, or be further shaped to form, the dispersion plate 105.

As part of steps 410 and 415, one skilled in the pertinent arts would be familiar with the pressure and temperature conditions appropriate for sintering together various types of metallic or inorganic non-metallic material particles to form a unitary dispersion plate. As part of steps 410 and 415, one skilled in the pertinent art would understand how to adjust the size or sizes of different particles and sintering procedures to achieve a targeted size, distribution and density of openings and/or the orientation of the holes and/or porosity or thickness of the plate 105 such as discussed above in the context of FIGS. 1-3.

As further illustrated in FIG. 4, some embodiments of the method 400 can include a step 425 of shaping the dispersion plate to fit a mounting location in a reactor assembly 160. In some embodiments, as part of step 425 the mold used in step 410 is shaped to provide a negative image of the exact target shape of the dispersion plate 105. In some embodiments, as part of step 425, the sintered material treated in step 415 or the material layer treated in step 420, is further cut, grinded, trimmed or otherwise shaped to form the target shape of the plate 105.

As also illustrated in FIG. 4, some embodiments of the method 400 can include a step 430 of mounting the dispersion plate 105 to a mounting location of a reactor assembly 160. In some cases, as part of step 430, the dispersion plate 105 can be secured to the reactor assembly 160 via screws, rivets or similar mounting structures placed through mounting holes 225 formed in the plate 105.

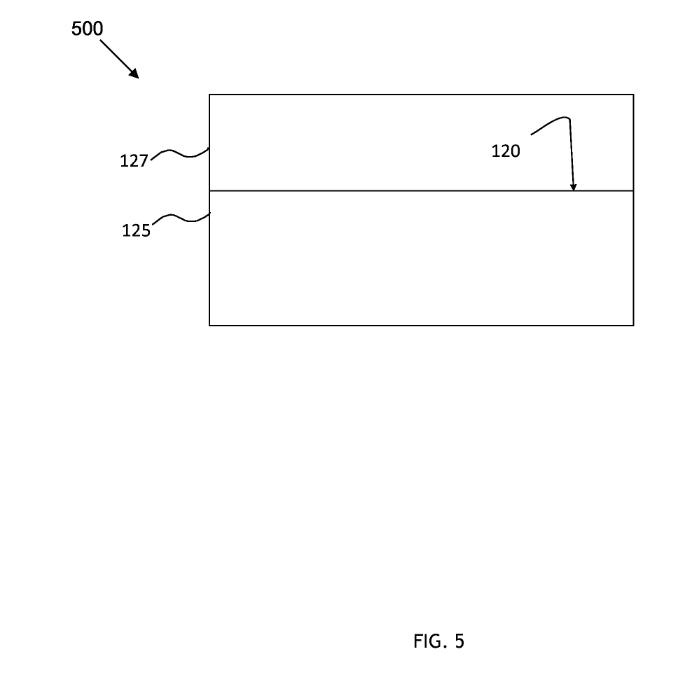

Another embodiment is a circuit, e.g., a planar lightwave circuit. FIG. 5 presents a detailed cross-sectional view of a circuit 500, such as a circuit having at least one component that is at least partially fabricated by any of the apparatus embodiments discussed in the context of FIGS. 1-4.

As illustrated in FIG. 5, the circuit 500 comprises a doped film 127 on a substrate 125, the film 127 including one or more dopants elements having an atomic number 21 or higher, wherein the film 127 has a light loss of about 2 dB/m or less.

For instance the light losses of 2 dB/m or less occur when passing a light beam (e.g., emitted from a laser) horizontally (e.g., parallel to the substrate surface 120) through the film 127. In some embodiments, the light loss is about 1 dB/m or less and in some embodiments, about 0.5 dB or less.

In some embodiments, the light losses refer to light at one or more wavelengths in ranges typically used in optical communications, e.g., one or more of the S band (1460 nm-1530 nm), the C band (1530 nm-1565 nm) or the L band (1565 nm-1625 nm) ranges. However, similar low levels of light loss at other frequencies is no precluded.

In some embodiments, the doped film 127 is substantially free of defects (e.g., isolated opaque regions or defect clusters in the film). That is, embodiments of the doped film 127 can be free of defects that are visible to the naked eye, and/or defects that are below a threshold that causes substantial light losses. For instance, in some cases the layer 127 is free of defects having an average diameter of greater than 500 microns, and in some embodiments, greater than about 100 microns. In some embodiments, the doped film 127 can be free of defects having an average diameter of greater than about 10 microns, and in some embodiments, greater than about 1 microns. This is in contrast to doped films formed using a conventional dispersion plate. Such films, can have a uniform pattern of millimeter-sized defects in the film that are visible to the naked eye, e.g., the pattern of defects matching the pattern of openings located in the dispersion plate.

In some embodiments the film 127 has a defect density per unit area of the doped film is at least 10 times and in some cases at least 100 times lower than that obtained using a conventional dispersion plate. For instance, consider a doped film 127 formed using a plate having 1 mm diameter of straight through-holes that are perpendicular to planar surface of the output side 115, where the adjacent through-holes are separated by 1 mm. If the defect density in doped film formed using this plate equal equals 50 defects per 100 mm² area, then the doped film 127 formed using an embodiment of the dispersion plate 105 discussed in the context of FIGS. 1-4 can have a defect density of less than 10 defects per 100 mm² area, and in some cases, less than 1 defect per 100 mm² area of the doped film 127.

In some embodiments the dopant in the doped film 127 includes one or more different types of rare earth elements. In some embodiments, the dopant includes rare earth elements used in optical devices, such as, one or more of neodymium, ytterbium, erbium, thulium, praseodymium or cerium. Alternatively, or additionally, in other embodiments the dopant includes transition metal elements having an atomic numbers or 40 or higher.

In some embodiments, the dopant concentration in the doped film 127 has a value in a range from about 10¹⁷ to 10¹⁹ atoms per cm³ of the film 127.

In some embodiments, the dopant in the doped film 127 has a uniform concentration throughout the film 127. For example, in some embodiments, any 10 percent contiguous, convex volume of the film 127 has about the same average concentration (within 10 percent) of dopant as any other different 10 percent contiguous, convex volume of the film. For example, in some embodiments, any 1 percent contiguous, convex volume of the film 127 has a same average concentration (within 10 percent) of dopant as any other different 1 percent contiguous, convex volume of the film.

In some embodiments, the doped film 127 is substantially formed of silicon dioxide, glass, or other monocrystalline or polycrystalline materials used in optical communication circuits. For instance, in some embodiments the film 127 is a waveguide in an optical laser, a diode or an optical amplifier in a planar lightwave circuit 500. For instance, in some embodiments, the doped film 127 can be pattern to be a waveguide in a laser composed of yttrium aluminum garnet, yttrium aluminate (YAlO₃) or yttrium tungstate.

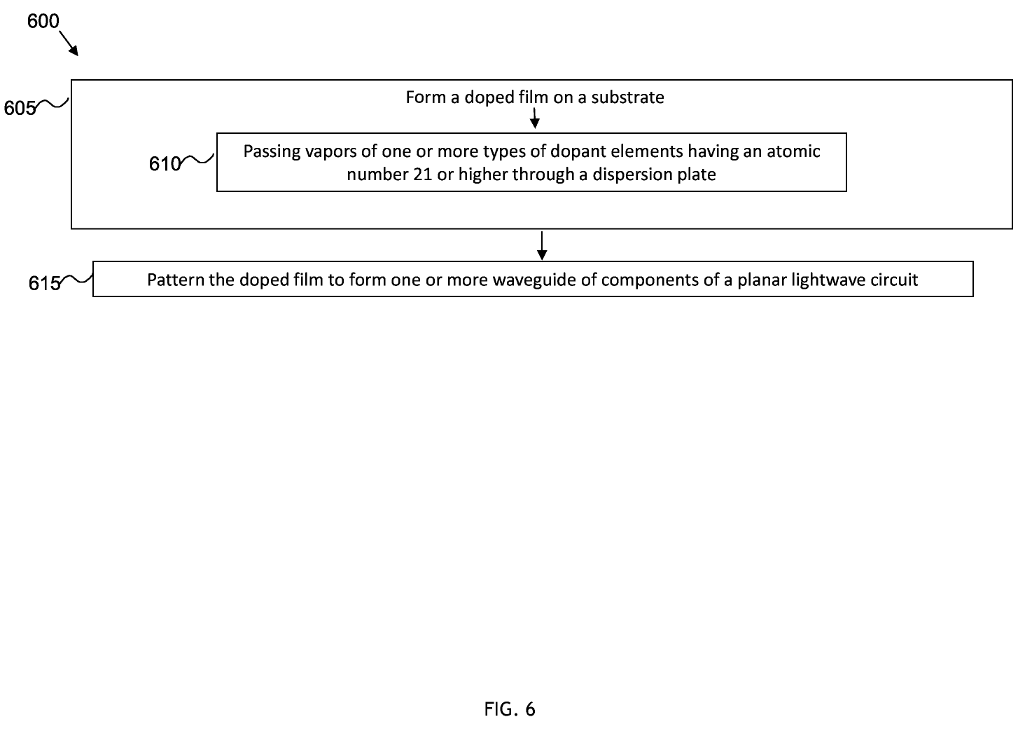

Another embodiment is a method, e.g., a method of fabricating a circuit, such as a PLC. FIG. 6 presents a flow diagram of a method 600, such as a method to fabricating any circuit described in the context of FIG. 5. With continuing reference to FIGS. 1-3 throughout, as illustrated in FIG. 6, the method comprises a step 605 of forming a doped film 127 on a substrate 125.

Forming the doped film 127 includes a step 610 of passing vapors of one or more types of dopant elements 110 having an atomic number 21 or higher through a dispersion plate 105, the dispersion plate 105 including holes 310 therein. The dispersion plate 105 includes input side openings 305 connected to holes 310 therein, the holes 310 following a torturous path through the dispersion plate 105 and configured to deliver dopants through output side openings 210 of the dispersion plate 105.

In some embodiments of the method 600, the doped film 127 formed in step 605 is epitaxially grown on a silicon substrate or other semiconductor substrate familiar to those skilled in the pertinent arts.

In some embodiments of the method 600, as part of step 610, the vapors of dopant elements are mixed (e.g., inside a reactor assembly 160, with deposition gases of the film 127 (e.g., saline, nitrous oxide or other gases) before passing through the dispersion plate 105.

In some embodiments of the method 600, the vapors of dopant elements include one or more types of rare earth elements coordinated with ligands to form coordination compounds. Non-limiting examples of such ligand include hexafluoroacetylacetonates (HFAA), acetylacetonates (AA), tetramethylheptanedionates (TMHD) or fluorooctanedionates (FOD). The formation of such rare earth element coordination compounds advantageously facilitate the formation of the doped films 127 at reduced temperatures suitable for commercially available CVD apparatuses. This is in contrast to the need to apply temperatures of 900° C. or higher if, e.g., chloride salts of rare earth elements are used as the dopants 110.

For instance in some embodiments of the method 600, the dispersion plate 105 is maintained at a temperature of about 700° C. or less while passing the vapors through the dispersion plate 105. For instance in some embodiments dispersion plate 105 is maintained at a temperature in a range of about 500 to 700° C., and in some embodiments, about 550 to 650° C. In some embodiments the dispersion plate 105 is maintained in a deposition chamber 165 at such temperature and pressures of 0.1 to 1 Torr.

One skilled in the pertinent arts would be familiar with other steps to facilitate the fabrication of a circuit in accordance with the method 600. For instance, in some embodiments the method further includes a step 615 of patterning the doped film to form one or more waveguide of components (e.g., a laser, or amplifier component) of a planar lightwave circuit.

Although the present disclosure has been described in detail, a person of ordinary skill in the relevant arts should understand that they can make various changes, substitutions and alterations herein without departing from the scope of the invention.

What is claimed is:

1. A chemical vapor deposition apparatus, comprising:
a dispersion plate, the dispersion plate including input side openings connected to holes therein, the holes following a torturous path through the dispersion plate and configured to deliver dopants through output side openings of the dispersion plate.

2. The apparatus of claim 1, wherein end openings of the through-holes have an average diameter of 400 microns or less and the average diameter of the through-holes is greater than an average diameter of the individual dopant molecules.

3. The apparatus of claim 1, wherein an average area of the output side of the holes has a standard deviation of about ±20 percent.

4. The apparatus of claim 1, wherein the output side openings of the holes have a smaller average diameter on than the average diameter of the input side openings.

5. The apparatus of claim 1, wherein an average separation distance between adjacent ones of the output side openings are substantially equal to the average diameter of the output side openings.

6. The apparatus of claim 1, wherein one or more major axes of the holes are substantially non-perpendicular to plane of an output surface of the dispersion plate.

7. The apparatus of claim 1, wherein torturous path of the holes includes at least one internal bend region which forms a bend angle of at least about 30 degrees between two different major axes of different portions of the same hole.

8. The apparatus of claim 1, wherein the holes form an interconnected porous network.

9. The apparatus of claim 1, wherein the plate is composed of an electrically conductive material.

10. The apparatus of claim 1, further including:
a reactor assembly configured to hold the dispersion plate inside of a deposition chamber, the reactor assembly configured to be coupled to a gas delivery system.

11. The apparatus of claim 1, wherein the dispersion plate is configured to regulate exposure of an adjacent surface of a deposition substrate to gases delivered to the reactor assembly, the gases including the dopants having elements of atomic number 21 or higher.

12. A method, comprising:
forming a dispersion plate of a chemical vapor deposition apparatus, the dispersion plate including input side openings connected to holes therein, the holes following a torturous path through the dispersion plate and configured to deliver dopants through output side openings of the dispersion plate.

13. The method of claim 12, wherein forming the dispersion plate includes:
placing metallic or inorganic non-metallic material particles into a mold of the dispersion plate; and
sintering adjacent ones of the particles to together to form the dispersion plate wherein open spaces between the sintered together particles correspond to the through-holes of the dispersion plate.

14. A circuit, comprising:
a doped film on a substrate, the film including one or more dopants elements having an atomic number 21 or higher, wherein the film has a light loss of about 2 dB/m or less.

15. The circuit of claim 14, wherein the light losses are at wavelengths in the S band, C band or L band range.

16. The circuit of claim 14, wherein the doped film is substantially free of individual defect clusters each having diameter of greater than about 500 microns.

17. The circuit of claim 14, wherein the doped film includes rare earth element dopants.

18. A method, comprising:
forming a doped film on a substrate, including:
passing vapors of one or more types of dopant elements having an atomic number 21 or higher through a dispersion plate, the dispersion plate including through-holes therein, the dispersion plate including input side openings connected to holes therein, the holes following a torturous path through the dispersion plate and configured to deliver dopants through output side openings of the dispersion plate.

19. The method of claim 18, wherein the dispersion plate is maintained at a temperature of about 700° C. or less while passing the vapors through the dispersion plate.

20. The method of claim 18, further including patterning the doped film to form one or more waveguides of component of a planar lightwave circuit.
